(19) United States
(12) Patent Application Publication
(10) Pub. No.: US 2018/0002160 A1
(43) Pub. Date: Jan. 4, 2018

(54) MEMS DEVICE AND PROCESS

(71) Applicant: Cirrus Logic International Semiconductor Ltd., Edinburgh (GB)

(72) Inventors: Marek Sebastian PIECHOCINSKI, Edinburgh (GB); Colin Robert JENKINS, Linlithgow (GB); Clive Robert GRAHAM, Edinburgh (GB)

(73) Assignee: Cirrus Logic International Semiconductor Ltd., Edinburgh (GB)

(21) Appl. No.: 15/636,825

(22) Filed: Jun. 29, 2017

(30) Foreign Application Priority Data
Jun. 30, 2016 (GB) 1611412.6
Jun. 30, 2016 (GB) PCT/GB2016/051974

(51) Int. Cl. B81B 3/00; B81C 1/00; H01L 41/09; B81C 3/00; H04R 31/00; H04R 19/04

(52) U.S. Cl. CPC B81B 3/0021; H04R 31/006; H04R 19/04; H01L 41/0973; B81C 3/001; B81C 1/00158; B81B 2203/0127

(57) ABSTRACT

The application describes MEMS transducer structures comprising a membrane structure having a flexible membrane layer and at least one electrode layer. The electrode layer is spaced from the flexible membrane layer such that at least one air volume extends between the material of the electrode layer and the membrane layer. The electrode layer is supported relative to the flexible membrane by means of a support structure which extends between the first electrode layer and the flexible membrane layer.

### FIELD OF DISCLOSURE

This invention relates to a micro-electro-mechanical system (MEMS) device and process, and in particular to a MEMS device and process relating to a transducer, for example a capacitive microphone.

### BACKGROUND

Various MEMS devices are becoming increasingly popular. MEMS transducers, and especially MEMS capacitive microphones, are increasingly being used in portable electronic devices such as mobile telephones and portable computing devices.

Microphone devices formed using MEMS fabrication processes typically comprise one or more membranes with electrodes for read-out/drive deposited on the membranes and/or a substrate. In the case of MEMS pressure sensors and microphones, the read out is usually accomplished by measuring the capacitance between a pair of electrodes which will vary as the distance between the electrodes changes in response to sound waves incident on the membrane surface.

FIGS. 1a and 1b show a schematic diagram and a perspective view, respectively, of a known capacitive MEMS microphone device 100. The capacitive microphone device 100 comprises a membrane layer 101 which forms a flexible membrane which is free to move in response to pressure differences generated by sound waves. A first electrode 102 is mechanically coupled to the flexible membrane, and together they form a first capacitive plate of the capacitive microphone device. A second electrode 103 is mechanically coupled to a generally rigid structural layer or back-plate 104, which together form a second capacitive plate of the capacitive microphone device. In the example shown in FIG. 1a the second electrode 103 is embedded within the back-plate structure 104.

The capacitive microphone is formed on a substrate 105, for example a silicon wafer which may have upper and lower oxide layers 106, 107 formed thereon. A cavity 108 in the substrate and in any overlying layers (hereinafter referred to as a substrate cavity) is provided below the membrane, and may be formed using a “back-etch” through the substrate 105. The substrate cavity 108 connects to a first cavity 109 located directly below the membrane. These cavities 108 and 109 may collectively provide an acoustic volume thus allowing movement of the membrane in response to an acoustic stimulus. Interposed between the first and second electrodes 102 and 103 is a second cavity 110.

The first cavity 109 may be formed using a first sacrificial layer during the fabrication process, i.e. using a material to define the first cavity which can subsequently be removed, and depositing the membrane layer 101 over the first sacrificial material. Formation of the first cavity 109 using a sacrificial layer means that the etching of the substrate cavity 108 does not play any part in defining the diameter of the membrane. Instead, the diameter of the membrane is defined by the diameter of the first cavity 109 (which in turn is defined by the diameter of the first sacrificial layer) in combination with the diameter of the second cavity 110 (which in turn may be defined by the diameter of a second sacrificial layer). The diameter of the first cavity 109 formed using the first sacrificial layer can be controlled more accurately than the diameter of a back-etch process performed using a wet-etch or a dry-etch. Etching the substrate cavity 108 will therefore define an opening in the surface of the substrate underlying the membrane 101.

A plurality of holes, hereinafter referred to as bleed holes 111, connect the first cavity 109 and the second cavity 110.

As mentioned the membrane may be formed by depositing at least one membrane layer 101 over a first sacrificial material. In this way the material of the membrane layer(s) may extend into the supporting structure, i.e. the side walls, supporting the membrane. The membrane and back-plate layer may be formed from substantially the same material as one another, for instance both the membrane and back-plate may be formed by depositing silicon nitride layers. The membrane layer may be dimensioned to have the required flexibility whereas the back-plate may be deposited to be a thicker and therefore more rigid structure. Additionally various other material layers could be used in forming the back-plate 104 to control the properties thereof. The use of a silicon nitride material system is advantageous in many ways, although other materials may be used, for instance MEMS transducers using polysilicon membranes are known.

In some applications, the microphone may be arranged in use such that incident sound is received via the back-plate. In such instances a further plurality of holes, hereinafter referred to as acoustic holes 112, are arranged in the back-plate 104 so as to allow free movement of air molecules, such that the sound waves can enter the second cavity 110. The first and second cavities 109 and 110 in association with the substrate cavity 108 allow the membrane 101 to move in response to the sound waves entering via the acoustic holes 112 in the back-plate 104. In such instances the substrate cavity 108 is conventionally termed a “back volume”, and it may be substantially sealed.

In other applications, the microphone may be arranged so that sound may be received via the substrate cavity 108 in use. In such applications the back-plate 104 is typically still provided with a plurality of holes to allow air to freely move between the second cavity and a further volume above the back-plate.

It should also be noted that whilst FIG. 1 shows the back-plate 104 being supported on the opposite side of the membrane to the substrate 105, arrangements are known where the back-plate 104 is formed closest to the substrate with the membrane layer 101 supported above it.

In use, in response to a sound wave corresponding to a pressure wave incident on the microphone, the membrane is deformed slightly from its equilibrium or quiescent position. The distance between the membrane electrode 102 and the backplate electrode 103 is correspondingly altered, giving rise to a change in capacitance between the two electrodes that is subsequently detected by electronic circuitry (not shown). The bleed holes allow the pressure in the first and second cavities to equalise over a relatively long timescale (in acoustic frequency terms) which reduces the effect of low frequency pressure variations, e.g. arising from temperature variations and the like, but without impacting on sensitivity at the desired acoustic frequencies.

The flexible membrane layer of a MEMS transducer generally comprises a thin layer of a dielectric material—such as a layer of crystalline or polycrystalline material. The membrane layer may, in practice, be formed by several layers of material which are deposited in successive steps. The flexible membrane 101 may, for example, be formed from silicon nitride Si₃N₄ or polysilicon. Crystalline and polycrystalline materials have high strength and low plastic deformation, both of which are highly desirable in the construction of a membrane. The membrane electrode 102 of a MEMS transducer is typically a thin layer of metal, e.g. aluminium, which is typically located in the centre of the membrane 101, i.e. that part of the membrane which displaces the most. It will be appreciated by those skilled in the art that the membrane electrode may be formed by an alloy such as aluminium-silicon for example. The membrane electrode may typically cover, for example, around 40% of area of the membrane, usually in the central region of the membrane.

Thus, known transducer membrane structures are composed of two layers of different material—typically a dielectric layer (e.g. SiN) and a conductive layer (e.g. AlSi).

Typically the membrane layer 101 and membrane electrode 102 may be fabricated so as to be substantially planar in the quiescent position, i.e. with no pressure differential across the membrane, as illustrated in FIG. 1a. The membrane layer may be formed so as to be substantially parallel to the back-plate layer in this quiescent position, so that the membrane electrode 102 is parallel to the back-plate electrode 103. However, over time, the membrane structure may become deformed—e.g. as a consequence of relatively high or repeated displacement—so that it will not return to exactly the same starting position.

A number of problems are associated with the previously considered transducer designs. In particular both the membrane and the membrane electrode will suffer intrinsic mechanical stress after manufacture, for instance due to being deposited at relatively high temperatures of a few hundred degrees Celsius and desiring on return to room temperature to contract by different amounts due to greatly different thermal coefficients of expansion yet being intimately mechanically coupled together. Not being able to immediately dissipate the stored energy due to the stress, i.e. not able to fully release the stress by independent mechanical contraction, the composite structure of electrode and membrane will tend to deform, similar to the well-known operation of bi-metallic strip thermostat sensors. Over a long time, especially when subject to repeated mechanical exercising as typical of a microphone membrane in use, the metal electrode layer in particular may be subject to creep or plastic deformation as it anneals to reduce its stored stress energy—being unable to release it in any other way. Thus, the equilibrium or quiescent position of the membrane structure comprising the membrane and the membrane electrode is sensitive to manufacturing conditions from day one and can also change over time.

FIG. 2 illustrates the permanent deformation which can occur to the quiescent position of the membrane 101/102. It can be seen that the quiescent position of the membrane, and thus the spacing between the back-plate electrode 103 and the membrane electrode 102, therefore changes from its position immediately after manufacture—shown by the dashed line—to the deformed quiescent position. This can lead to a DC offset in the measurement signal from such a transducer, as the capacitance at the quiescent position is not the same. More importantly, for a.c. audio signals, the change in capacitance leads to a variation in the signal charge for a given acoustic stimulus, i.e. the acousto-electrical sensitivity of the microphone.

In addition, the elasticity of the composite electrode-membrane structure 101/102 is sensitive to the mechanical stress of the electrode and membrane layers. Any variation in manufacturing conditions and the subsequent stress release via metal creep or suchlike will affect the values of the stress of these layers. The deformation due to the stress mismatch will also directly affect the values of quiescent stress.

Thus, it can be appreciated that the membrane structure and associated transducer may suffer an increased manufacturing variation in initial sensitivity and furthermore experience a change—or drift—in sensitivity over time meaning that the transducer performance cannot be kept constant.

Furthermore, the metal of the membrane electrode may undergo some plastic deformation as a consequence of relatively high or repeated displacement from the quiescent/equilibrium position. Thus, the metal of the membrane electrode may be deformed so it will not return to its original position. Since the flexible membrane 101 and the membrane electrode 102 are mechanically coupled to one another this can also lead to an overall change in the quiescent position of the flexible membrane 101 and/or a change in the stress properties and thus the elasticity of the overall membrane structure.

### SUMMARY

Embodiments of the present invention relate to MEMS transducers and processes which seek to alleviate some of the aforementioned disadvantages, in particular by providing a transducer which exhibits an improved consistency in sensitivity or performance initially and over time.

According to a first aspect of the present invention there is provided a MEMS transducer comprising a membrane structure, the membrane structure comprising a flexible membrane layer and a first electrode layer, the first electrode layer being supported relative to the flexible membrane layer so as to be spaced from the flexible membrane layer.

The separation of the electrode layer from the membrane layer advantageously serves to reduce coupling of initial post-manufacture or time-dependent stress differences between electrode layer and membrane layer and thus advantageously alleviate problems associated with the warping of the membrane structure and elasticity variation due to coupled stress, both initially and over time. Initial manufacturing variation and drift over time of transducer sensitivity may also be improved. The supporting of the electrode relative to the flexible membrane layer allows the electrode layer to still substantially mechanically follow the movement of the membrane layer to deliver an output signal despite the separation.

The first electrode layer is preferably supported relative to the flexible membrane by means of a support structure which extends between the first electrode layer and the flexible membrane layer.

According to embodiments of the invention, at least one air volume extends between the material of the first electrode layer and the membrane layer.

The membrane structure may comprise a second electrode layer, said second electrode layer being disposed on the opposite side of the flexible membrane to the first electrode. Preferably, the second electrode layer is supported relative to the flexible membrane layer so as to be spaced from the flexible membrane layer.

Preferably, the second electrode layer is supported relative to the flexible membrane by means of a support structure which extends between the second electrode layer and the flexible membrane layer.

According to embodiments of the present invention, the first electrode layer and/or the second electrode layer may comprise a continuous sheet of material. Alternatively, the first electrode layer and/or the second electrode layer comprises one or more openings. The openings in the may be generally circular in shape and/or the openings may be non-circular in shape. Thus, the first electrode layer and/or the second electrode layer may be formed in a lattice shape. The lattice shape may comprise a plurality of polygons which define openings in the electrode layer. Thus, the first and/or second electrode layer can be considered to comprise a lattice of connectivity which is suspended relative to the membrane layer by means of a support structure.

The electrode layer may have a thickness of around 100 nm. The electrode layer may be spaced from the membrane layer by a separation of around 100 nm.

The support structure which serves to facilitate the suspension of the/each electrode layer above/below the membrane layer may comprise a plurality of support elements. The support elements comprise dielectric or conductive material. The support elements may be disposed at or near the periphery of the membrane structure. Alternatively the support elements may be distributed over the surface of the membrane.

Alternatively, the support structure which serves to facilitate the suspension of the/each electrode layer above/below the membrane layer, may comprise a conductive layer having a plurality of openings. Thus, the support structure may comprise a lattice structure.

Alternatively, the support structure may comprise (only) a first partial lattice structure, and the electrode layer may comprise only a second partial lattice structure, the first and second lattice structures cooperating to provide electrical connection to all desired elements of the electrode layer.

It will be appreciated that the first and/or second electrode layer may be fabricated—e.g. by deposition—as a distinct processing step. Alternatively, the first and/or second electrode layer may be fabricated during deposition of a single layer of material which is subsequently processed to form the support structure and the electrode layer. Thus, embodiments of the present invention are envisaged in which the support structure is formed of the same material as the electrode layer. Preferably, however, the bulk of the conductive material forms the electrode layer which is suspended relative to the flexible membrane with the support structure layer. Alternatively, embodiments of the present invention are envisaged in which the support structure is formed of the same material as the membrane layer.

According to embodiments of the present invention, the openings of the support structure form a plurality of air volumes which extend between the material of the first electrode layer and the flexible membrane layer. The openings of the support structure may increase in size from a region towards the centre of the membrane structure to a region at or near the periphery of the membrane structure. Alternatively, the openings of the support structure may be substantially of uniform size.

In embodiments wherein the electrode layer and the support layer each comprise a plurality of openings, the openings of the electrode layer may be laterally offset from the openings of the support layer.

The first electrode layer (as a substantially continuous sheet or lattice pattern or partial lattice pattern) may overlie substantially all of the membrane or there may be a region of the membrane where the electrode layer or pattern is absent. This region may comprise at least a central region of the membrane.

The flexible membrane may comprise a crystalline or polycrystalline material. Preferably the flexible membrane layer comprises silicon nitride. The first and/or second electrode layer may comprise metal or a metal alloy. Preferably, the electrode comprises aluminium, silicon, doped silicon, aluminium-silicon alloy, polysilicon or titanium nitride.

Embodiments of the present invention advantageously demonstrate a reduction in the degree of deformation of the quiescent or equilibrium position of the membrane structure over time. The separation of the first electrode layer from the membrane layer serves to at least partially decouple the electrode material from the membrane material in one or more regions thus mitigating the mis-match between the mechanical properties of the membrane and the conductive electrode. Thus embodiments of the present invention advantageously reduce the area of interface between the membrane material and the metal electrode, thereby serving to reduce the mechanical influence of the metal electrode layer on the membrane layer. According to preferred embodiments the time-dependent drift of the MEMS transducer is alleviated. Furthermore, embodiments of the present invention may demonstrate an enhancement in the capacitance, since the overall working area of the electrode layer can be advantageously increased within existing electrode boundaries. As a result, the sensitivity of the transducer may be enhanced.

Some of the invention relate to structures of the electrode layer or support structures which allow relaxation of stress of the electrode layer, thus advantageously reducing any impact on the stress or deformation of the membrane, and so reducing any consequent sensitivity variation, initially or over time.

The transducer may comprise a back-plate structure wherein the flexible membrane layer is supported with respect to said back-plate structure. The back-plate structure may comprises a plurality of holes through the back-plate structure.

The transducer may be a capacitive sensor such as a microphone. The transducer may comprise readout, i.e. amplification, circuitry. The transducer may be located within a package having a sound port, i.e. an acoustic port. The transducer may be implemented in an electronic device which may be at least one of: a portable device; a battery powered device; an audio device; a computing device; a communications device; a personal media player; a mobile telephone; a tablet device; a games device; and a voice controlled device.

Features of any given aspect may be combined with the features of any other aspect and the various features described herein may be implemented in any combination in a given embodiment.

Associated methods of fabricating a MEMS transducer are provided for each of the above aspects.

### BRIEF DESCRIPTION OF THE DRAWINGS

For a better understanding of the present invention and to show how the same may be carried into effect, reference will now be made by way of example to the accompanying drawings in which:

FIGS. 1a and 1b illustrate known capacitive MEMS transducers in section and perspective views;

FIG. 2 illustrates how a membrane may be deformed;

FIG. 3 illustrates a previously considered membrane structure;

FIGS. 4a to 4e show cross-sectional views through various membrane structures according to embodiments of the present invention;

FIGS. 5a to 5e show a membrane structure according to a further embodiment of the present invention;

FIGS. 6a to 6d show further membrane structures according to embodiments of the present invention;

FIGS. 7a to 7g show cross-sectional views through various membrane structures according to further embodiments of the present invention; and

FIGS. 8 to 8h show a series of drawings to illustrate a process for making a membrane structure embodying the present invention.

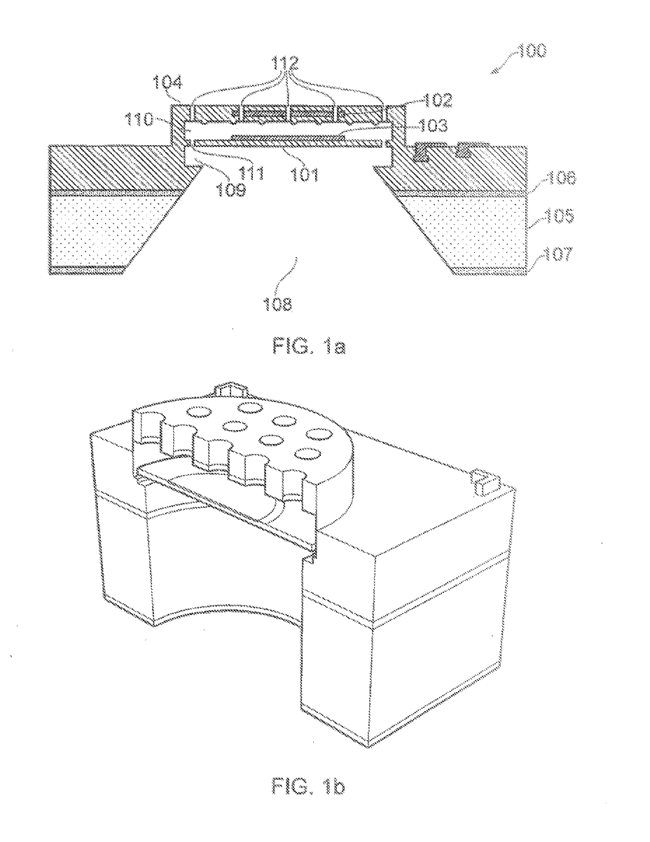

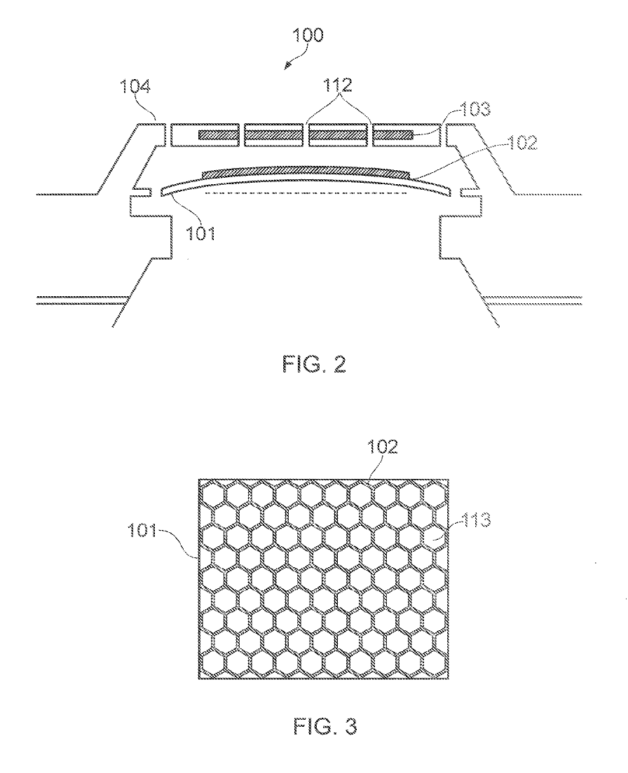

Throughout this description any features which are similar to features in other figures have been given the same reference numerals.

### DETAILED DESCRIPTION

FIG. 3 shows a top view of a previously considered membrane structure comprising a planar membrane layer 101 and an electrode 102. The electrode—which is typically formed of metal or metal alloy—is patterned to incorporate a plurality of openings 113. In this specific example the openings are generally hexagonal in shape.

It will be appreciated that microphone sensitivity is a function of capacitance which is directly proportional to the area of the conductive electrode. Membrane structures which incorporate a patterned electrode layer, or lattice, as shown in FIG. 3 may therefore potentially demonstrate a deterioration in the sensitivity of the transducer as compared to sheet electrode designs, albeit mitigated somewhat by the effect of electrostatic fringing fields.

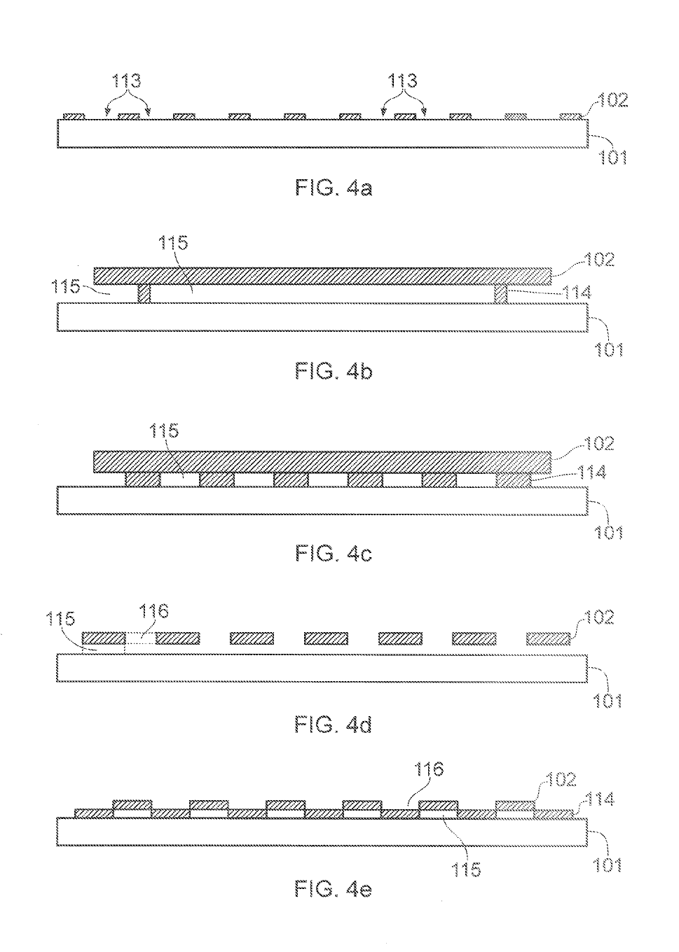

FIGS. 4a to 4e each show a cross-sectional view through various membrane structures comprising a flexible membrane 101 and a first electrode.

FIG. 4a shows a cross section through the line A-A of the membrane structure shown in FIG. 3. The metal forming the electrode 102 can be seen to be directly in contact with the flexible membrane layer 101. Thus any stress in the electrode is directly coupled into the membrane, and the electrode can substantially only attempt to relax its stress by affecting the membrane stress.

FIG. 4b shows a cross-sectional view of a membrane structure for a MEMS transducer according to a first embodiment of the present invention. The membrane structure comprises a first electrode layer 102 comprising a sheet electrode which is supported, by means of a support structure comprising a plurality of support elements 114, in a spaced relationship from the membrane layer 101. A volume of air 115 extends between the electrode layer and the flexible membrane. The support elements 114 may comprise a plurality of vertical spacers, or isolated mounts, which allow the first electrode layer to be suspended above the membrane layer. The membrane structure may be provided with such support elements provided around some or all of the periphery of the membrane, near to parts of the periphery at which the membrane is anchored by means not illustrated in this figure to the surrounding silicon substrate. The elements serve to establish a spacing of the electrode layer in the vertical direction—i.e. orthogonally to the plane of the membrane—without significantly coupling the electrode layer in the plane of the membrane. The support elements may be formed of conductive or dielectric material. Alternatively both the membrane and the electrode may be anchored independently, for instance at the sidewall of the backplate, with the electrode anchored at a higher part of the sidewall than the electrode such that the sidewall provides the support structure as illustrated in Figure X, in the structure shown on the left. Thus in some embodiments the support structure may comprise a continuous structure, for example a continuous ring around a circular periphery.

The volume of air substantially trapped between the electrode and the membrane may be substantially trapped, except maybe for bleed holes in the membrane structure or electrode layers, or with limited access to other volumes of the structure via the periphery of the membrane. The volume of air may thus serve as an air cushion to couple any acoustically stimulated movement of the membrane to the electrode.

Thus, according to this embodiment, it will be appreciated that the electrode layer is physically separated from the membrane (although it will also be appreciated that the electrode layer is indirectly connected to the membrane layer via the support elements 114). As such, since the electrode layer is not in direct contact with the membrane layer except at or near the periphery, the mechanical influence of the electrode layer 102 on the membrane layer is reduced and the membrane structure may advantageously demonstrate an improvement in time-dependent warping of the membrane. Moreover, in comparison to the membrane structure shown in FIGS. 3 and 4a, the area of the metal electrode is increased and, thus, the transducer sensitivity is enhanced.

FIG. 4c shows a cross-sectional view of a membrane structure for a MEMS transducer according to a second embodiment of the present invention. The membrane structure comprises a first electrode layer 102 and a support structure 114. The first electrode layer 102 comprises a continuous sheet of electrode material. The support structure 114 comprises a patterned layer of conductive material—similar to the single electrode layer shown in FIG. 4a—comprising a plurality of openings. The openings define a plurality of air volumes 115—which extend between the first electrode layer 102 and the membrane layer 101. In this example the material of the first electrode layer, the metal elements of the lattice structure forming the support structure 114 and the membrane effectively form a plurality of closed air volumes within the membrane structure. Thus, as a consequence of the electrode layer not being connected to the membrane layer at each of the air volumes, a significant proportion of the electrode material of the first electrode layer is mechanically separate from the membrane layer, thereby allowing at least some stress release by local vertical thinning of the electrode material. Although illustrated as approximately equal, preferably the support structure is significantly less wide than the air volume width, to allow increased stress relaxation.

FIG. 4d shows a cross sectional view of a membrane structure for a MEMS transducer according to a third embodiment of the present invention. The first electrode layer 102 comprises a layer of electrode material that is patterned to comprise a plurality of openings 116 within the plane of the first electrode layer. Although not apparent from this cross-sectional view, the electrode layer 102 is formed in a lattice shape—e.g. by a process of patterning or etching of the electrode material. The lattice shaped electrode can be considered to comprise a plurality of interconnected conductive elements. The first electrode layer 102 is supported so as to be spaced from the membrane layer by means of one or more support elements (not shown) which may be formed of the same material as the electrode or of an insulating material.

The first electrode layer 102 can be seen to define a plurality of interconnected electrode elements which extend in the line of the cross sectional view. Each of the electrode elements can be considered to form a conductive bridge with the space underneath the bridge defining an air volume 115 as indicated by the dashed line. Each arm or bridge of the lattice is free to expand or contract in width or height proving degrees of freedom to allow any metal stress to be substantially accommodated leaving only relatively little residual stress requiring to be released via transmission to the membrane via the support elements.

FIG. 4e shows a cross sectional view of a membrane structure for a MEMS transducer according to a fourth embodiment of the present invention. In this example the first electrode layer 102 again comprises a layer of electrode material that is patterned to comprise a plurality of openings 116 within the plane of the first electrode layer. Again, as in FIG. 4d, the electrode layer 102 is formed in a lattice shape and can be considered to comprise a plurality of interconnected conductive elements. The electrode layer is supported in a spaced relation relative to the membrane layer by means of a support structure.

The support structure 114 is patterned to incorporate a plurality of openings. The electrode layers are fabricated such that the openings of the electrode layer are laterally offset from the openings of the support structure. This figure portrays an illustrative case in which the bridges and support structures are at least somewhat aligned along the chosen cross-sectional plane: for e.g. a hexagonal lattice there will be no such plane, but this figure illustrates the general concept of the bridges linked by a series of conductive support structures.

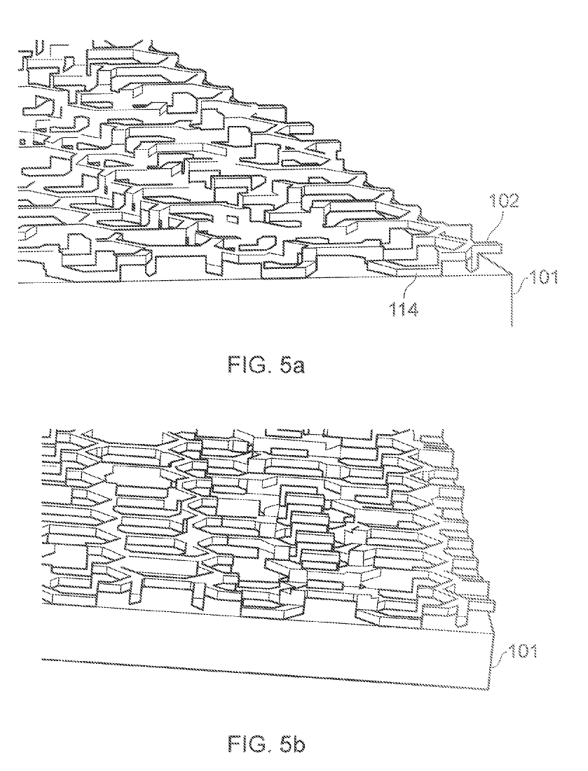

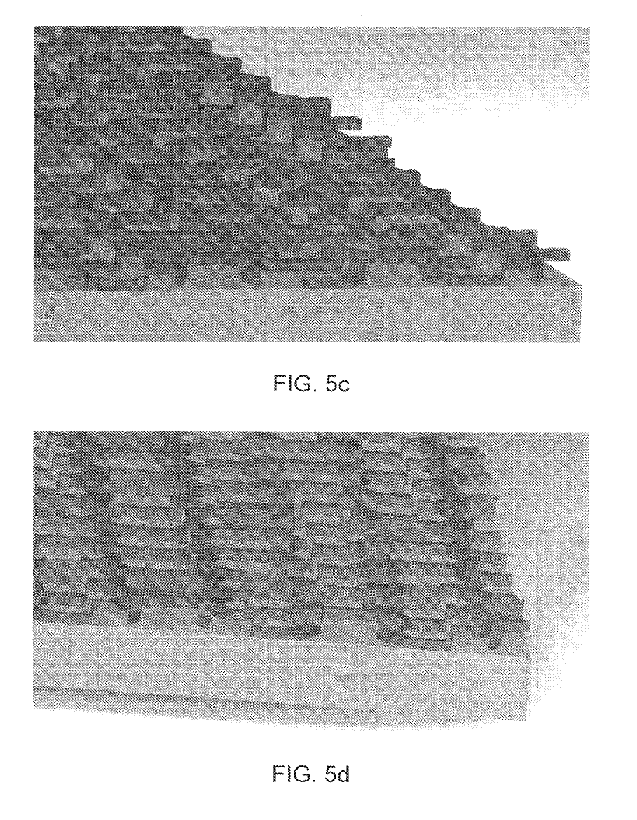

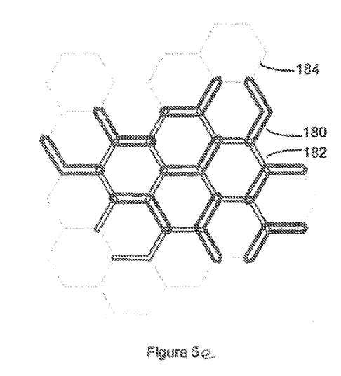

FIGS. 5a to 5e show perspective views of a membrane structure according to a fifth embodiment of the present invention. In this example the electrode layer 102 is patterned to incorporate a plurality of openings. Specifically, the electrode layer is spaced from the membrane layer by means of a support structure 114. The support structure 114 in this embodiment comprises the same conductive material that forms the electrode layer 102. The support structure 114 thus extends between the electrode layer 102 and the membrane 101.

As illustrated most clearly in the plan view of FIG. 5e, the support structure may comprise a first partial lattice structure comprising elements 182, and the electrode layer may comprise a second partial lattice structure comprising elements 180, laid out superimposed on a hexagonal grid pattern 184. The individual separate elements of the first partial lattice structure serve as conductive bridges between adjacent elements of the second partial lattice structure, which in turn provide conductive paths between the adjacent elements of the first partial lattice structure. Thus the first and second lattice structures cooperate to provide electrical connection to all desired elements of the electrode layer. Some or all elements at or near the periphery of the membrane may be coupled to readout circuitry, thus coupling the whole electrode structure to the readout circuitry.

The elements of the first partial lattice structure are isolated and small so accumulate little stress and are free to release this stress in several directions. The elements of the second partial lattice structure are isolated and small so accumulate little stress, so also have little effect on the membrane. In further variants, the size of the elements of the second partial lattice structure may be reduced further, for instance by spanning only a part of each edge of the polygon rather than the whole side, with the adjacent electrode element expanded to maintain connectivity.

In variants illustrated in perspective in FIGS. 5a and 5b, elements of the first partial lattice structure are extended laterally in a cantilever fashion to increase their area to increase the sensing capacitance.

FIGS. 5c and 5d are photographic illustrations of a membrane structure as illustrated in FIGS. 5a and 5b.

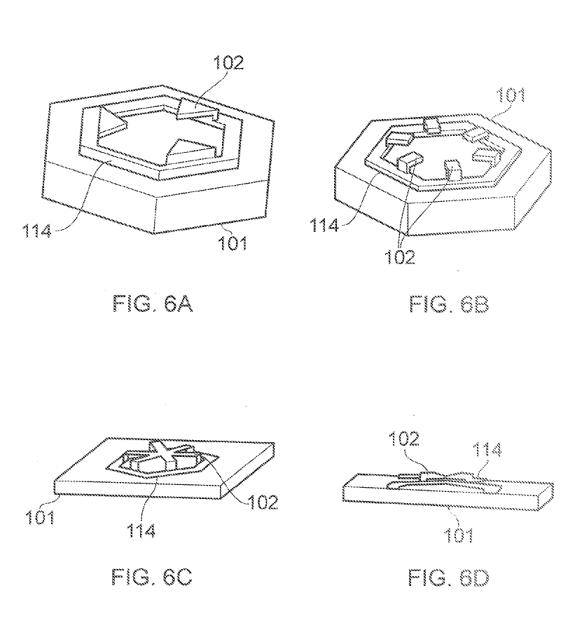

As illustrated in FIGS. 6a and 6b, which also further illustrate cantilever structures, a membrane structure embodying the present invention in which the electrode comprises material that is spaced from the flexible membrane layer and thus incorporates one or more air volumes which extend between the spaced material and the membrane layer, may be fabricated from further processing to the electrode structure shown in FIG. 3. Thus, the material that will form the first electrode layer can be deposited onto a patterned electrode layer as shown in FIG. 3 (which ultimately forms the support structure for the first electrode layer) so that the material of the first electrode layer extends partially or fully between opposite edges defining the openings of the support layer. As shown in FIGS. 6a and 6b the material of the first electrode layer 102 is therefore spaced from the membrane layer by an air volume and thus forms a cantilever or “partial cross-over” with respect to the plane of the support structure 114. As shown in FIGS. 6c and 6d, the material of the first electrode layer 114 forms a “full cross-over” with respect to the plane of the support structure 114. The resultant membrane structure will benefit from increased capacitance due to the increased conductive material, whilst the openings of the support structure provide an improvement in the stresses that arise between the electrode material and the membrane as comparted to previously considered designs incorporating a single electrode layer comprising a continuous sheet of metal in direct contact with the membrane.

According to one or more embodiments of the present invention, the mechanical decoupling of the electrode layer by the presence of one or more air volumes which extend between the first electrode layer and the membrane layer could be beneficially used to alleviate so-called diaphragm edge curl. In view of the problem of the membrane curling at the edge due to the stress mis-match that arises between the two layers, it is typical for the conductive metal electrode material to be deposited in region towards the centre of the membrane and not close to the edge of the membrane. However, this prior solution represents a reduction in the metal electrode area and thus undermines the sensitivity of the transducer. Embodiments of the present invention enable the electrode to extend over a greater proportion of the membrane including the region at or near the periphery of the membrane.

According to preferred embodiments which utilise a support structure comprising a lattice-like structure in conjunction with an electrode layer also comprising a lattice-like structure, it is proposed to vary the area of the openings provided in electrode layer and/or the area of the openings in the support structure so as to control or modulate membrane edge curl. Edge curl leads to air leakage around the membrane, i.e. an acoustic bypass path which particularly impairs low-frequency sensitivity and so controlling the edge curl allows for more effective control of the leakage and, thus, improved control of microphone low-frequency roll-off.

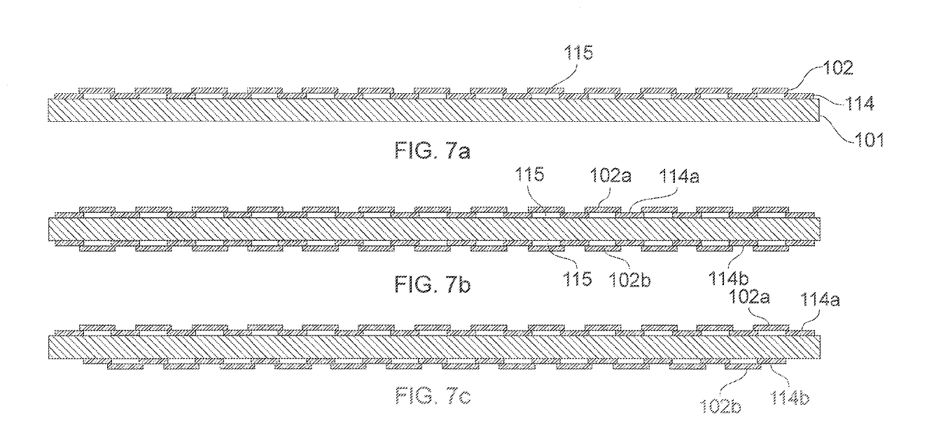

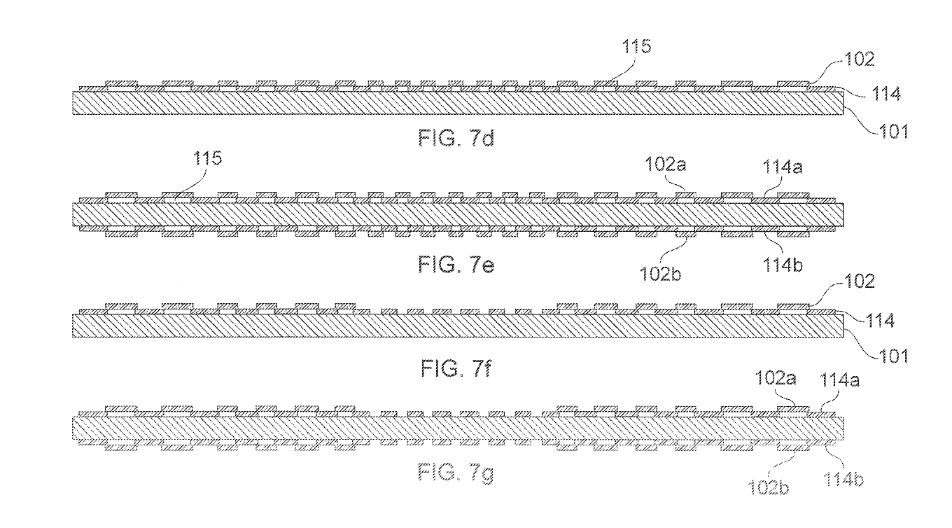

FIGS. 7a to 7g each show a cross-sectional view through various membrane structure designs which comprise a flexible membrane layer 101 and at least a first electrode 102 supported in a spaced relation from the membrane by means of a support structure 114.

FIG. 7a shows a membrane structure comprising a first electrode layer 102a and a support layer 114. Both the first electrode layer and the support layer are patterned to incorporate a plurality of openings. The openings formed in the support layer form a plurality of air volumes 115 which extend between the first electrode layer and the membrane layer. In this example the size of the openings across the membrane layer is substantially constant.

FIG. 7b shows a membrane structure comprising a first electrode layer 102a and a second electrode layer 102b. The second electrode layer 102b is formed on the opposite side of the flexible membrane layer 101 to the first electrode 102a. Each of the first and second electrode layers 102a, 102b is supported in fixed relation relative to the flexible membrane by a support layer 114a, 114b such that the material forming the respective electrode layer is supported in spaced relation from the membrane and is thus separated from the membrane layer by a plurality of air volumes 115 formed by openings 115 in the respective support layer. In this example the size of the openings 115 across the membrane layer is substantially constant.

A membrane structure according to FIG. 7b may be usefully employed in conjunction with a MEMS transducer which utilises first and second backplates (each incorporating a backplate electrode) which are respectively positioned above and below the membrane structure.

FIG. 7c shows a membrane structure that is similar to the membrane structure shown in FIG. 7b. However, in this example the air volumes 115 of the second electrode are laterally offset with respect to the openings of the first electrode. This arrangement can beneficially serve to mitigate the occurrence of stress concentrations arising within the membrane structure since the stress arising between the membrane and the first electrode may tend to cancel or mitigate the stress maxima and minima arising between the membrane and the second electrode. Furthermore, a membrane structure embodying this design may experience a rippling effect which therefore provides a degree of freedom to the membrane and, thus, alleviates stress. Again, in this example the size of the openings across the membrane layer is substantially constant.

FIG. 7d shows a membrane structure comprising a first electrode layer 102a and a support layer 114. Both the first electrode layer and the support layer are patterned to incorporate a plurality of openings. The openings formed in the support layer form a plurality of air volumes 115 which extend between the first electrode layer and the membrane layer. In this example the size of the openings in both the first electrode layer and the support layer vary from a region at the centre of the membrane towards an outer or peripheral region of the membrane. Thus, the openings which form the air volumes 115 similarly vary in size. Specifically, the area of the air volumes 115 formed by the openings in the support layer increase in size from a region towards the centre of the membrane to a region at or near the periphery of the membrane. This arrangement—specifically the increase in the size of the openings towards the periphery of the membrane structure—advantageously serves to mitigate membrane edge curl.

FIG. 7e shows a membrane structure comprising a first electrode layer 102a and a second electrode layer 102b. The second electrode layer 102b is formed on the opposite side of the flexible membrane layer 101 to the first electrode 102a. Each of the first and second electrode layers 102a, 102b is supported in fixed relation relative to the flexible membrane by a support layer 114a, 114b such that the material forming the respective electrode layer is supported in spaced relation from the membrane and is thus separated from the membrane layer by a plurality of air volumes 115 formed by openings 115 in the respective support layer. As in the example shown in FIG. 7d, the size of the openings in both the electrode layer and the support layer vary from a region at the centre of the membrane towards an outer or peripheral region of the membrane. Thus, the openings which form the air volumes 115 similarly vary in size. Specifically, the area of the air volumes 115 formed by the openings in the support layer increase in size from a region towards the centre of the membrane to a region at or near the periphery of the membrane. The increase in the size of the openings towards the periphery of the membrane structure advantageously serves to mitigate membrane edge curl since it serves to reduce local fractional metal area coverage to thereby reduce stress in the peripheral region. Furthermore, the trade off in terms of a reduced capacitance is less critical since the membrane experiences less displacement than the central region of the membrane structure.

A membrane structure according to FIG. 7e may be usefully employed in conjunction with a MEMS transducer which utilises first and second backplates (each incorporating a backplate electrode) which are respectively positioned above and below the membrane structure.

FIG. 7f shows a membrane structure comprising an electrode layer 102 and a support layer 114. According to this example, the electrode layer 102 does not extend over a central region of the flexible membrane layer. Thus, within the central region of the membrane structure, the first electrode is formed only of a single support layer which is provided so as to directly overlay the membrane layer 101. Furthermore, the size of the openings in support layer 114 increase from a region at or near the boundary of the central region to a region at or near the periphery of the membrane in a manner similar to the embodiment shown in FIG. 7e. In the region laterally outside the central region of the membrane—i.e. the region where the electrode layer is spaced above the membrane layer by means of the underlying support layer 114, the openings in the support layer form air volumes 115 which extend between the electrode layer and the membrane.

Transducers incorporating membrane structures embodying the FIG. 7f example are advantageous in that the electrode layer 102 need be provided on just a fraction of the membrane structure—e.g. on around 10% of the area of the membrane—in the peripheral region of the membrane. Thus, the presence of decoupling air-bridges, or air volumes, are provided at the edge of the membrane structure which may beneficially mitigate membrane edge-curl.

FIG. 7g shows an example similar to the FIG. 7f example however, the membrane structure comprising a first electrode layer 102a and a second electrode layer 102b. The second electrode layer 102b is formed on the opposite side of the flexible membrane layer 101 to the first electrode 102a.

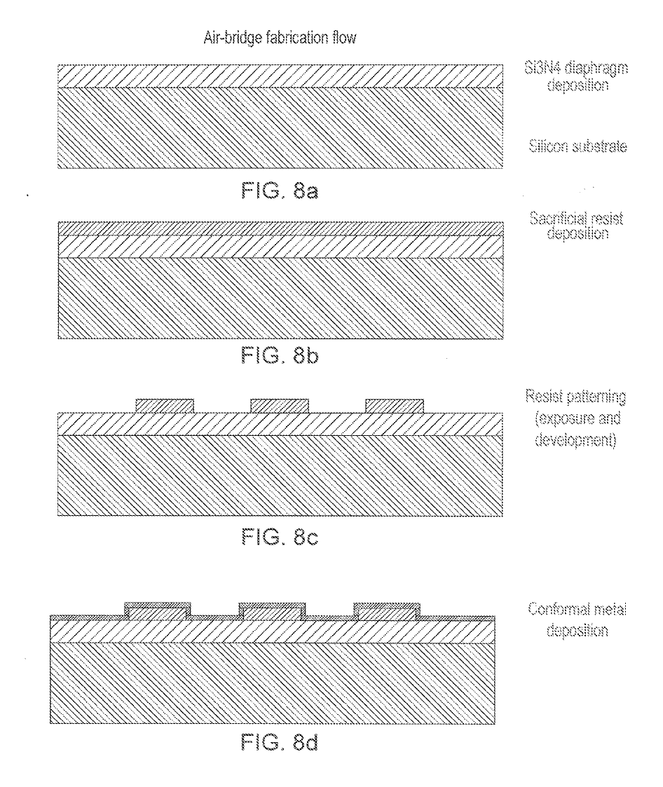

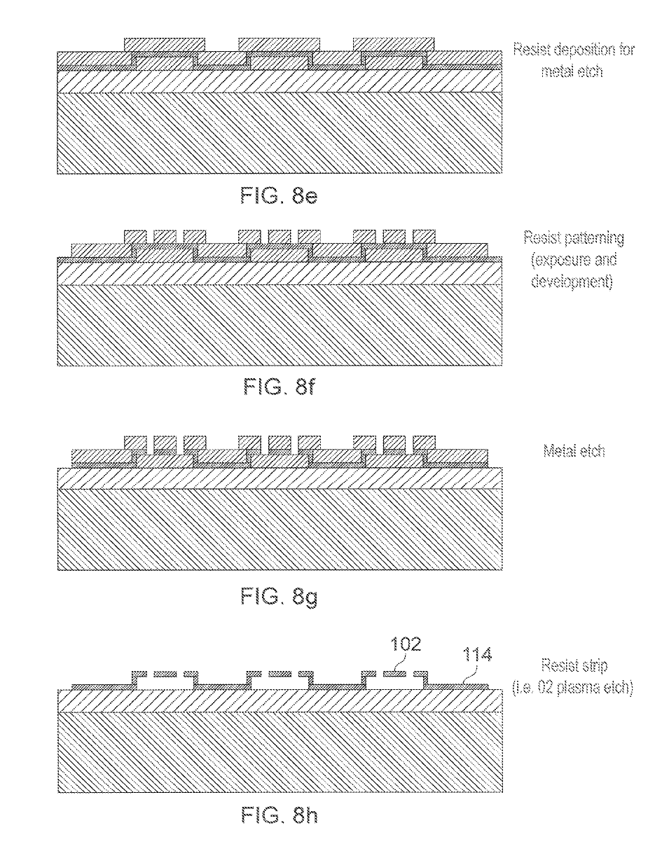

FIGS. 8a to 8h illustrate the steps involved in a possible method of fabricating a membrane structure according to one embodiment of the present invention.

As shown in FIG. 8a, the microfabrication process starts with the deposition of silicon nitride (Si₃N₄) onto a planar silicon substrate wafer using known techniques such as a PECVD (plasma enhanced chemical vapour deposition) method.

In FIG. 8b, a sacrificial resist layer is deposited on top of the silicon nitride and this is then patterned (exposure and development) as shown in FIG. 8c. A metal electrode is deposited by conformal coating using e.g. a sputtering technique as shown in FIG. 8d. Then, a second layer of resist is deposited on top of the metal layer—as shown in FIG. 8e—which is then patterned as shown in FIG. 8f. Reactive ion etch is applied to create metal perforation as shown in FIG. 8g. Both resist layers are stripped in the last fabrication step, shown in FIG. 8h to create a layer of metal forming the electrode layer with air volumes underneath in spaces previously filed by the sacrificial resist layer, and the support layer comprising the sidewalls of the conformal metal coating as well as the metal portions directly contacting the substrate. Portions of the underlying substrate may be etched from below in a later step of the process to release the nitride membrane layer. The support metal may extend laterally to electrically connect the electrode structure to associated bias or amplifier circuitry which may either be co-integrated on the same substrate or may be integrated on a separate silicon substrate and coupled via bond pads or contact pads.

A MEMS transducer according to the embodiments described here may comprise a capacitive sensor, for example a microphone.

A MEMS transducer according to the embodiments described here may further comprise readout circuitry, for example wherein the readout circuitry may comprise analogue and/or digital circuitry such as a low-noise amplifier, voltage reference and charge pump for providing higher-voltage bias, analogue-to-digital conversion or output digital interface or more complex analogue or digital signal processing. There may thus be provided an integrated circuit comprising a MEMS transducer as described in any of the embodiments herein.

One or more MEMS transducers according to the embodiments described here may be located within a package. This package may have one or more sound ports. A MEMS transducer according to the embodiments described here may be located within a package together with a separate integrated circuit comprising readout circuitry which may comprise analogue and/or digital circuitry such as a low-noise amplifier, voltage reference and charge pump for providing higher-voltage bias, analogue-to-digital conversion or output digital interface or more complex analogue or digital signal processing.

A MEMS transducer according to the embodiments described here may be located within a package having a sound port.

According to another aspect, there is provided an electronic device comprising a MEMS transducer according to any of the embodiments described herein. An electronic device may comprise, for example, at least one of: a portable device; a battery powered device; an audio device; a computing device; a communications device; a personal media player; a mobile telephone; a games device; and a voice controlled device.

According to another aspect, there is provided a method of fabricating a MEMS transducer as described in any of the embodiments herein.

Although the various embodiments describe a MEMS capacitive microphone, the invention is also applicable to any form of MEMS transducers other than microphones, for example pressure sensors or ultrasonic transmitters/receivers.

Embodiments of the invention may be usefully implemented in a range of different material systems, however the embodiments described herein are particularly advantageous for MEMS transducers having membrane layers comprising silicon nitride.

In the embodiments described above it is noted that references to a transducer element may comprise various forms of transducer element. For example, a transducer element may comprise a single membrane and back-plate combination. In another example a transducer element comprises a plurality of individual transducers, for example multiple membrane/back-plate combinations. The individual transducers of a transducer element may be similar, or configured differently such that they respond to acoustic signals differently, e.g. the elements may have different sensitivities. A transducer element may also comprises different individual transducers positioned to receive acoustic signals from different acoustic channels.

It is noted that in the embodiments described herein a transducer element may comprise, for example, a microphone device comprising one or more membranes with electrodes for read-out/drive deposited on the membranes and/or a substrate or back-plate. In the case of MEMS pressure sensors and microphones, the electrical output signal may be obtained by measuring a signal related to the capacitance between the electrodes. However, it is noted that the embodiments are also intended to embrace the output signal being derived by monitoring piezo-resistive or piezo-electric elements or indeed a light source. The embodiments are also intended embrace a transducer element being a capacitive output transducer, wherein a membrane is moved by electrostatic forces generated by varying a potential difference applied across the electrodes, including examples of output transducers where piezo-electric elements are manufactured using MEMS techniques and stimulated to cause motion in flexible members.

It is noted that the embodiments described above may be used in a range of devices, including, but not limited to: analogue microphones, digital microphones, pressure sensor or ultrasonic transducers. The invention may also be used in a number of applications, including, but not limited to, consumer applications, medical applications, industrial applications and automotive applications. For example, typical consumer applications include portable audio players, wearable devices, laptops, mobile phones, PDAs and personal computers. Embodiments may also be used in voice activated or voice controlled devices. Typical medical applications include hearing aids. Typical industrial applications include active noise cancellation. Typical automotive applications include hands-free sets, acoustic crash sensors and active noise cancellation.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfill the functions of several units recited in the claims. Any reference signs in the claims shall not be construed so as to limit their scope.

1. A MEMS transducer comprising a membrane structure, the membrane structure comprising a flexible membrane layer and a first electrode layer, the first electrode layer being supported relative to the flexible membrane layer so as to be spaced from the flexible membrane layer.

2. A MEMS transducer as claimed in claim 1, wherein at least one air volume extends between the material of the first electrode layer and the membrane layer.

3. A MEMS transducer as claimed in claim 1, wherein the membrane structure comprises a second electrode layer, said second electrode layer being disposed on the opposite side of the flexible membrane to the first electrode.

4. A MEMS transducer as claimed in claim 3, wherein the second electrode layer is supported relative to the flexible membrane layer so as to be spaced from the flexible membrane layer.

5. A MEMS transducer as claimed in claim 1, wherein the first electrode layer comprises a continuous sheet of material.

6. A MEMS transducer as claimed in claim 1, wherein the first electrode layer comprises one or more openings.

7. MEMS transducer as claimed in claim 1, wherein the first electrode layer comprises a lattice structure.

8. A MEMS transducer as claimed in claim 1, wherein the first electrode layer is supported relative to the flexible membrane by means of a support structure which extends between the first electrode layer and the flexible membrane layer.

9. A MEMS transducer as claimed in claim 3, wherein the second electrode layer is supported relative to the flexible membrane by means of a support structure which extends between the second electrode layer and the flexible membrane layer.

10. A MEMS transducer as claimed in claim 8, wherein the support structure comprises a plurality of support elements.

11. A MEMS transducer as claimed in claim 10, wherein the support elements comprise dielectric or conductive material.

12. A MEMS transducer as claimed in claim 10, wherein the support elements are disposed at or near the periphery of the membrane structure.

13. A MEMS transducer as claimed in claim 8, wherein the support structure comprises a conductive layer having a plurality of openings.

14. A MEMS transducer as claimed in claim 13, wherein the support structure comprises a lattice structure.

15. A MEMS transducer as claimed in claim 13, wherein the openings of the support structure form a plurality of air volumes which extend between the material of the first electrode layer and the flexible membrane layer.

16. A MEMS transducer as claimed in claim 13, wherein the openings of the support structure increase in size from a region towards the centre of the membrane structure to a region at or near the periphery of the membrane structure.

17. A MEMS transducer as claimed in claim 13, wherein the openings of the support structure are substantially of uniform size.

18. A MEMS transducer as claimed in claim 13, wherein the openings of the first electrode layer are laterally offset from the openings of the support structure.

19. A MEMS transducer as claimed in claim 1, wherein the first electrode layer comprises a hole which overlies at least a central region of membrane layer.

20. A MEMS transducer comprising a membrane structure, the membrane structure comprising a membrane and an electrode, wherein the material forming the electrode is separated from the membrane by at least one air volume.

21. A MEMS transducer as claimed in claim 1, wherein the flexible membrane comprises a crystalline or polycrystalline material.

22. A MEMS transducer as claimed in claim 21, wherein the flexible membrane layer comprises silicon nitride.

23. A MEMS transducer as claim in claim 1, wherein the first electrode layer comprises metal, a metal alloy or a metallic compound.

24. A MEMS transducer as claimed in claim 1, wherein said transducer comprises a capacitive microphone.

25. A MEMS transducer as claimed in claim 24, further comprising readout circuitry, the readout circuitry comprising one or both of analogue and digital circuitry.

26. An electronic device comprising a MEMS transducer as claimed in claim 1, wherein said device is at least one of: a portable device; a battery powered device; an audio device; a computing device; a communications device; a personal media player; a mobile telephone; a games device; and a voice controlled device.
